(19) United States
(12) Patent Application Publication
(10) Pub. No.: US 2006/0151865 A1
(43) Pub. Date: Jul. 13, 2006

(54) Semiconductor chip stack package having dummy chip

(76) Inventors: Chang-Hoon Han, Cheonan-si (KR); Sang-Ho An, Suwon-si (KR)

Correspondence Address: HARNESS, DICKEY & PIERCE, P.L.C., P.O. BOX 8910, RESTON, VA, 20195, US

(21) Appl. No.: 11/297,664

(22) Filed: Dec. 9, 2005

(30) Foreign Application Priority Data
Dec. 10, 2004 (KR) 2004-104246

(51) Int. Cl. H01L 23/02

(52) U.S. Cl. 257/686; 257/E23.085

(57) ABSTRACT

A chip stack package may have a circuit substrate, a first IC chip provided on the circuit substrate, and a second IC chip provided on the first IC chip. The second IC chip may be larger in size than the first IC chip and have overhang portions that may extend beyond edges of the first IC chip. At least one dummy chip may be provided on the second IC chip and cover the edges of the first IC chip. The dummy chip may include a single chip or a plurality of chips.

### PRIORITY STATEMENT

This U.S. non-provisional application claims benefit of priority under 35 U.S.C. §119 of Korean Patent Application No. 2004-104246, filed on Dec. 10, 2004, the entire contents of which are incorporated herein by reference.

### BACKGROUND

1. Field of the Invention

The present invention relates in general to a semiconductor packaging technique and, more particularly, to a semiconductor chip stack package that may have a dummy chip for reinforcing an overhang wire bonding structure.

2. Description of the Related Art

A trend may be to miniaturize semiconductor packages. To this end, multi-chip packaging techniques have been introduced. Moreover, portable communication products (for example) may perform multiple functions. Multi-chip packaging techniques may include a plurality of semiconductor chips having different functions in a single package. Although multi-chip packages manufactured using conventional techniques may generally provide acceptable results, they are not without shortcomings. For example, conventional multi-chip packages may be relatively thick. Accordingly, it may be desirable to provide semiconductor chips that are relatively thin. However, a semiconductor chip having a reduced thickness may result in faults.

For example, a chip stack package may have a thin semiconductor chip with an overhang portion that is wire bonded to a substrate. The wire bonding process, when performed on the overhang portion, may experience faults.

FIG. 1 is a cross-sectional view of an example of an overhang wire bonding structure of a conventional chip stack package 10. Here, the chip stack package 10 may include a circuit substrate 11. A first integrated circuit (“IC”) chip 12 may be provided on the circuit substrate 11. A second IC chip 13 may be provided on the first IC chip 12. The second IC chip 13 may be larger in size than the first IC chip 12. The second IC chip 13 may be mounted so that edges of the second IC chip 13 may extend outside corresponding edges of the first IC chip 12. In other words, the second IC chip 13 may have overhang portions 13b that may not be supported by the first IC chip 12.

The second IC chip 13 may have an active surface on which input/output (I/O) pads 13a are provided. The circuit substrate 11 may have a surface supporting bond pads 11a. Bonding wires 14 may connect the I/O pads 13a to the bond pads 11a to electrically connect the second IC chip 13 to the circuit substrate 11.

The I/O pads 13a of the second IC chip 13 may be positioned on the overhang portions 13b. During a wire bonding process, bonding pressure may result in wire bonding faults. FIG. 2 is a cross-sectional view showing a problem that may arise during wire bonding.

Referring to FIG. 2, a bonding capillary 15 may move downward over the overhang portion 13b of the second IC chip 13 to perform a wire bonding on the I/O pads 13a of the second IC chip 13. The bonding capillary 15 may press the overhand portion 13b, thereby generating a bouncing phenomenon. The bouncing phenomenon may result in incorrect and/or faulty wire bonding. Also, the pressure applied by the bonding capillary 15 may crack the overhang portion 13b.

To overcome such shortcomings, support members and/or other materials may be provided to support the overhang portion 13b. However, when the first IC chip 12 is electrically connected to the circuit substrate 11 using bonding wires (for example), it may be difficult to locate the support members and/or other materials below the overhang portion 13b. FIG. 3 is a cross-sectional view of another example of an overhang wire bonding structure of a conventional chip stack package 20, in which a first IC chip 12 may be electrically connected to a circuit substrate 11 using a bonding wire 17.

Referring to FIG. 3, the chip stack package 20 may include the circuit substrate 11 having bond pads 11a and 11b, the first IC chip 12, and the second IC chip 13 having overhang portions 13b. The first IC chip 12 may be provided on the circuit substrate 11 using a first adhesive 16. A first bonding wire 17 may electrically connect the first IC chip 12 to the bond pad 11b of the circuit substrate 11. The second IC chip 13 may be provided on the first IC chip 12 using a second adhesive 18. A second bonding wire 14 may electrically connect the second IC chip 13 to the bond pad 11a of the circuit substrate 11.

The first bonding wire 17 may be positioned below the overhang portions 13b of the second IC chip 13. Accordingly, it may be difficult to provide support members and/or other materials to support the overhang portions 13b.

### SUMMARY

According to an example, non-limiting embodiment of the present invention, a chip stack package may include a circuit substrate. A first IC chip may be provided on the circuit substrate using a first adhesive and may be electrically connected to the circuit substrate. A second IC chip may be larger in size than the first IC chip. The second IC chip may be provided on the first IC chip using a second adhesive and may be electrically connected to the circuit substrate using a second bonding wire. At least one dummy chip may be smaller in size than the second IC chip. The dummy chip may be provided on the second IC chip using a third adhesive layer. The second IC chip may have overhang portions that may extend beyond edges of the first IC chip. The dummy chip may cover the edges of the first IC chip

According to another example, non-limiting embodiment of the present invention, a package may include a first IC chip and a second IC chip provided on the first IC chip. The second IC chip may have an overhang portion that extends beyond an edge of the first IC chip. At least one dummy chip may be provided on the second IC chip. The at least one dummy chip may be superposed over an edge of the first IC chip.

According to another example, non-limiting embodiment of the present invention, a method of manufacturing a package may involve providing a first IC chip. A second IC chip may be provided on the first IC chip so that an overhang portion of the second IC chip extends beyond an edge of the first IC chip. At least one dummy chip may be provided on the second IC chip so that the at least one dummy chip superposes over an edge of the first IC chip.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a cross-sectional view of a conventional overhang wire bonding structure.

FIG. 2 is a cross-sectional view showing a problem associated with the conventional overhang wire bonding structure of FIG. 1.

FIG. 3 is a cross-sectional view of another conventional overhang wire bonding structure.

FIG. 4 is a plan view of a chip stack package having a dummy chip in accordance with an example, non-limiting embodiment of the present invention.

FIG. 5 is a cross-sectional view taken along the line of V-V of FIG. 4.

FIG. 6 is a plan view of a chip stack package having dummy chips in accordance with another example, non-limiting embodiment of the present invention.

FIG. 7 is a cross-sectional view taken along the line of VII-VII of FIG. 6.

FIG. 8 is a plan view of a chip stack package having dummy chips in accordance with another example, non-limiting embodiment of the present invention.

FIG. 9 is a cross-sectional view taken along the line of IX-IX of FIG. 8.

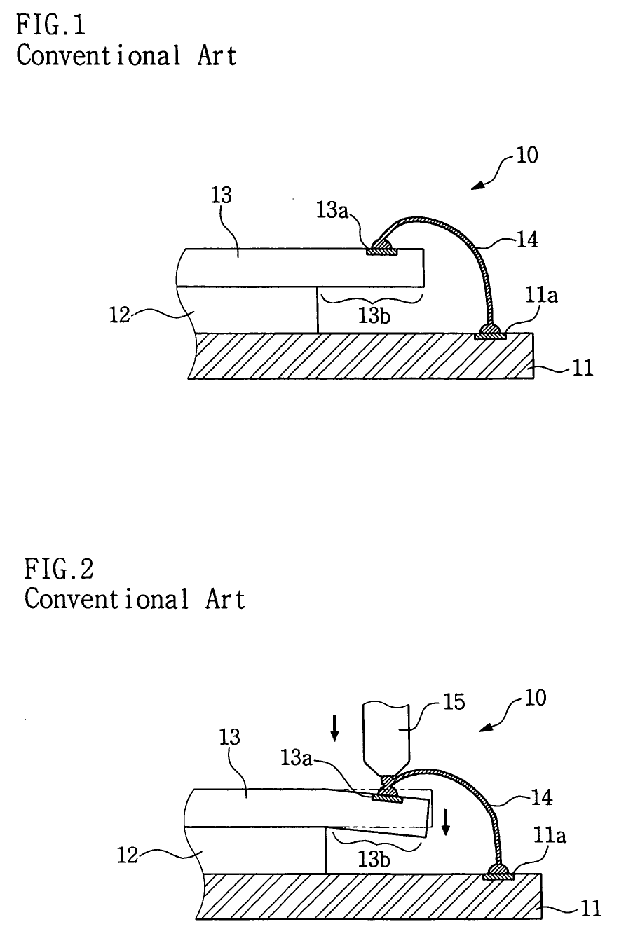

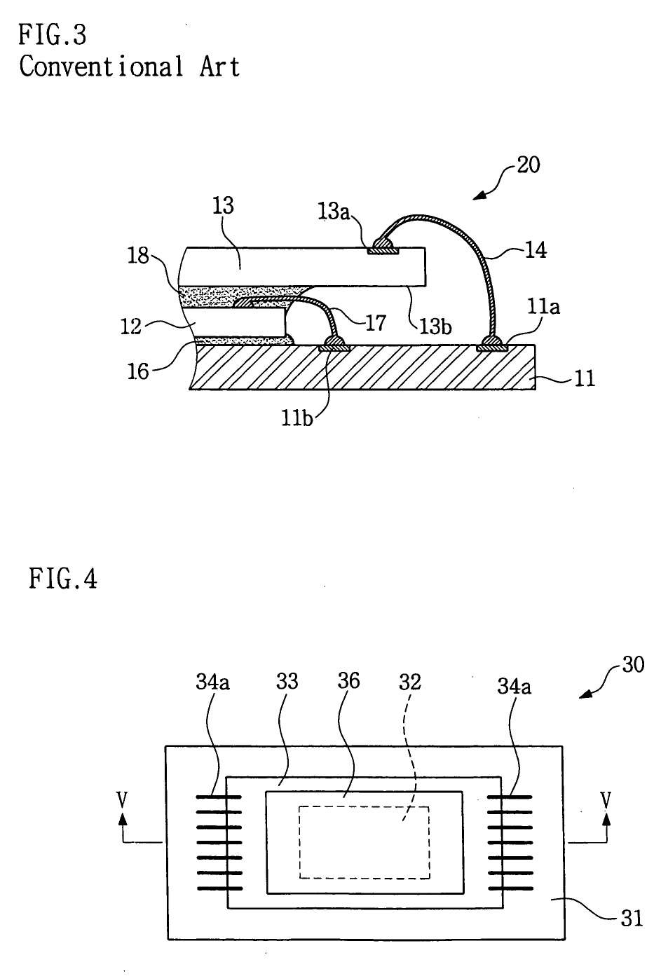

The drawings are provided for illustrative purposes only and are not drawn to scale. The spatial relationships and relative sizing of the elements illustrated in the various embodiments may be reduced, expanded and/or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF EXAMPLE EMBODIMENTS

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and feature of this invention may be employed in varied and numerous embodiments without departing from the scope of the invention.

Well-known structures and processes are not described or illustrated in detail to avoid obscuring the present invention. Further, a layer is considered as being formed (or provided) “on” another layer or a substrate when formed (or provided) either directly on the referenced layer or the substrate or formed (or provided) on other layers or patterns overlaying the referenced layer.

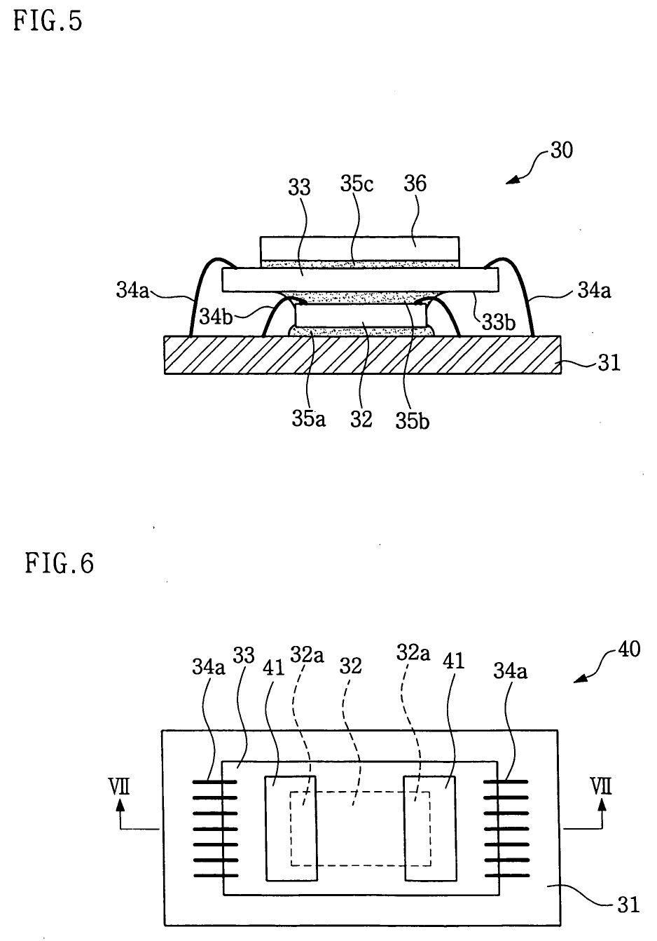

FIG. 4 is a plan view of a chip stack package 30 having a dummy chip 36 in accordance with an example, non-limiting embodiment of the present invention. FIG. 5 is a cross-sectional view taken along the line V-V of FIG. 4.

Referring to FIGS. 4 and 5, the chip stack package 30 may include a circuit substrate 31, a first IC chip 32, and a second IC chip 33. The first IC chip 32 may be provided on the circuit substrate 31 using a first adhesive layer 35a (for example). A first bonding wire 34b may electrically connect the first IC chip 32 to the circuit substrate 31. In an alternative embodiment, the first IC chip 32 may be electrically connected to the circuit substrate 31 via structure other than the first bonding wire 34b (e.g., the first IC chip 32 may be “flip chip” mounted and electrically connected to the circuit substrate 31 via solder bumps, as is well known in this art). The second IC chip 33 may be provided on the first IC chip 32 using a second adhesive layer 35b (for example). A second bonding wire 34a may electrically connect the second IC chip 33 to the circuit substrate 31.

The circuit substrate 31 may have a surface (facing toward the IC chips) supporting bond pads, and a surface (facing away from the IC chips) supporting solder bump pads. Vias may be provided in the circuit substrate 31, as is well known in this art. The circuit substrate 31 may be in the form of a printed circuit board, but it is not limited in this regard. The first adhesive layer 35a and the second adhesive layer 35b may each include a liquid adhesive and/or an adhesive film. In alternative embodiments, the adhesive layers 35a and 35b may be dispensed with in favor of other, alternative structures that may hold the component parts together. The first bonding wire 34b and second bonding wire 34a may be provided via a reverse bonding method. An example reverse bonding method may involve forming a ball bond on the circuit substrate 31, followed by forming a stitch bond on the IC chip (either the first or the second IC chip). In alternative embodiments, the first bonding wire 34b and the second bonding wire 34a may be provided using a conventional wire bonding method.

The second IC chip 33 may be larger in size than the first IC chip 32. The second IC chip 33 may be mounted so that the second IC chip 33 may have overhang portions 33b. In plan view, the overhang portions 33b may extend beyond edges of the first IC chip 32 so that the overhand portions 33b may not be supported by the first IC chip 32. The second bonding wire 34a may be connected to I/O pads (not shown) located on the overhang portions 33b to form an overhang wire bonding structure.

The chip stack package 30 may include a dummy chip 36. The dummy chip 36 may be provided on the second IC chip 33 using a third adhesive layer 35c (for example). The dummy chip 36 may be electrically isolated from the other component parts of the chip stack package 30. The dummy chip 36 may be fabricated from materials that are well known in this art. The dummy chip 36 may reinforce the overhang wire bonding structure. The dummy chip 36 may be smaller in size than the second IC chip 33 and larger than the first IC chip 32. The third adhesive layer 35c may include a liquid adhesive and/or an adhesive film. In alternative embodiments, the third adhesive layer 35c may be dispensed with in favor of other, alternative structures that may hold the component parts together.

The dummy chip 36 may support the overhang portions 33b of the second IC chip 33. Therefore, the likelihood of an overhang bouncing phenomenon may be reduced, thereby reducing wire bonding faults or cracking of the overhang portions 33b.

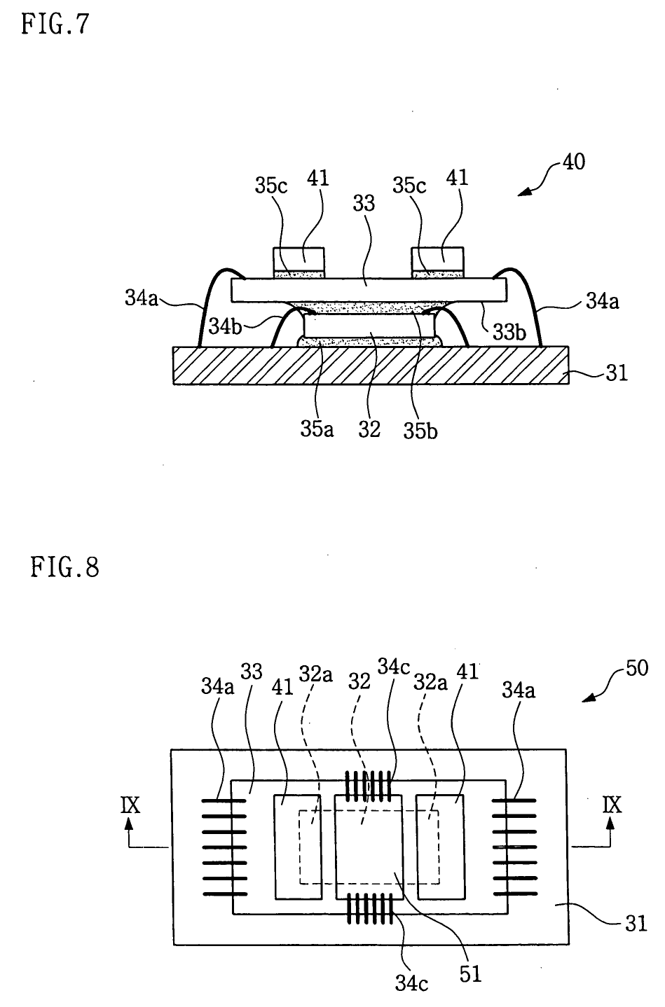

FIG. 6 is a plan view of a chip stack package 40 having dummy chips 41 in accordance with another example, non-limiting embodiment of the present invention. FIG. 7 is a cross-sectional view taken along the line VII-VII of FIG. 6.

Referring to FIGS. 6 and 7, the chip stack package 40 may have a similar structure as the chip stack package 30 depicted in FIGS. 4 and 5, except that a plurality of dummy chips 41 may be provided.

The dummy chips 41 may be provided on the second IC chip 33 using a third adhesive layer 35c (for example). The dummy chips 41 may be electrically isolated from the other component parts of the chip stack package 40. In plan view, the dummy chips 41 may cover edge portions 32a of the first IC chip 32.

The dummy chips 41 may support the overhang portions 33b of the second IC chip 33 in a similar manner as in the above described embodiment. By way of example only, two dummy chips 41 may be provided. In alternative embodiments, any other number of dummy chips 41 may be provided.

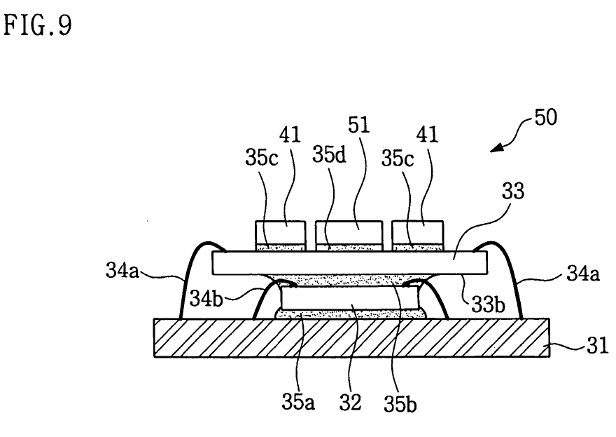

FIG. 8 is a plan view of a chip stack package 50 having dummy chips 41 in accordance with another example, non-limiting embodiment of the present invention. FIG. 9 is a cross-sectional view taken along the line IX-IX of FIG. 8.

Referring to FIGS. 8 and 9, the chip stack package 50 may have a similar structure as the chip stack package 40 depicted in FIGS. 6 and 7, except that a third IC chip 51 may be provided.

The third IC chip 51 may be provided between the dummy chips 41 and provided on the second IC chip 33 using a fourth adhesive layer 35d (for example). A third bonding wire 34c may electrically connect the third IC chip 51 to a circuit substrate 31. The fourth adhesive layer 35d may include a liquid adhesive and/or an adhesive film. In alternative embodiments, the fourth adhesive layer 35d may be dispensed with in favor of other, alternative structures that may hold the component parts together. The third bonding wire 34c may be formed using a reverse bonding method or a conventional wire bonding method. The orientation of the third bonding wire 34c may be different from that of the second bonding wire 34a.

The dummy chips 41 may support overhang portions 33b of the second IC chip 33 in a similar manner as in the above described embodiments.

The third IC chip 51 may support a portion of the second IC chip 33. Since the third IC chip 51 may be arranged between the dummy chips 41, the third IC chip 51 may not influence the thickness of the chip stack package 50.

A molding resin (not shown) may seal components formed on the circuit substrate 31 to protect them from the external environment. External connection terminals (not shown), for example solder bumps, may be formed on the surface (facing away from the IC chips) of the circuit substrate 31 to electrically connect the chip stack packages 30, 40 and 50 to external devices.

In accordance with the example, non-limiting embodiments of the present invention, at least one dummy chip may reinforce an overhang wire bonding structure of a chip stack package. Therefore, the present invention may reduce problems associated with an overhang wire bonding structure. For example, the bouncing of the overhang portion during wire bonding may be reduced, faulty wire bonding may be reduced, and cracking of the overhang portions may be reduced.

In the illustrated embodiments, the IC chips and the dummy chips may have a rectangular shape. In alternative embodiments, however, the IC chips and the dummy chips may have any other geometric shape. Further, as shown in the plan views of FIGS. 4, 6 and 8, the dummy chip may extend across the entire width of the underlying first IC chip 32. In alternative embodiments, the dummy chip may extend across only a portion of the width of the underlying first IC chip 32.

Although example, non-limiting embodiments of the present invention have been described in detail hereinabove, it should be understood that many variations and/or modifications of the basic inventive concepts, which may appear to those skilled in the art, will still fall within the spirit and scope of the example embodiments of the present invention as defined in the appended claims.

What is claimed is:

1. A package comprising:
a circuit substrate;
a first IC chip provided on the circuit substrate using a first adhesive layer and electrically connected to the circuit substrate;
a second IC chip being larger in size than the first IC chip, the second IC chip provided on the first IC chip using a second adhesive layer and electrically connected to the circuit substrate using a second bonding wire; and
at least one dummy chip being smaller in size than the second IC chip, the dummy chip provided on the second IC chip using a third adhesive layer;
wherein the second IC chip has overhang portions that extend beyond edges of the first IC chip; and
wherein the dummy chip covers the edges of the first IC chip.

2. The package of claim 1, wherein the first IC chip and the circuit substrate are electrically connected together using a first bonding wire.

3. The package of claim 2, wherein the first bonding wire forms a reverse bonding structure.

4. The package of claim 1, wherein the first adhesive layer includes one of a liquid adhesive and an adhesive film.

5. The package of claim 1, wherein the second adhesive layer includes one of a liquid adhesive and an adhesive film.

6. The package of claim 1, wherein the third adhesive layer includes an adhesive film.

7. The package of claim 1, wherein the at least one dummy chip includes a single dummy chip larger than the first IC chip.

8. The package of claim 1, wherein the at least one dummy chip includes a plurality of chips covering the edges of the first IC chip.

9. The package of claim 8, further comprising a third IC chip arranged between the dummy chips, the third IC chip provided on the second IC chip using a fourth adhesive layer and electrically connected to the circuit substrate.

10. The package of claim 9, wherein the third IC chip and the circuit substrate are electrically connected together using a third bonding wire.

11. The package of claim 10, wherein the orientation of the third bonding wire is different from the orientation of the second bonding wire.

12. The package of claim 9, wherein the fourth adhesive layer includes one of a liquid adhesive and an adhesive film.

13. A package comprising:
a first IC chip;
a second IC chip provided on the first IC chip, the second IC chip having an overhang portion that extends beyond an edge of the first IC chip; and
at least one dummy chip provided on the second IC chip, the at least one dummy chip superposed over the edge of the first IC chip.

14. The package according to claim 13, further comprising:
a circuit substrate supporting the first IC chip and electrically connected to the second IC chip.

15. The package according to claim 14, wherein the circuit substrate is electrically connected to the second IC chip using a bonding wire.

16. The package according to claim 15, wherein the bonding wire is connected to a pad on the overhang portion of the second IC chip.

17. The package according to claim 14, wherein the first IC chip is electrically connected to the circuit substrate using a bonding wire.

18. The package according to claim 13, wherein the at least one dummy chip includes a plurality of chips superposed over an edge of the first IC chip.

19. A method of manufacturing a package, the method comprising:
providing a first IC chip;
providing a second IC chip on the first IC chip so that an overhang portion of the second IC chip extends beyond an edge of the first IC chip; and
providing at least one dummy chip on the second IC chip so that the at least one dummy chip superposes over an edge of the first IC chip.

20. A package manufactured in accordance with the method of claim 19.
